(19) United States
(12) Patent Application Publication
(10) Pub. No.: US 2003/0020973 A1
(43) Pub. Date: Jan. 30, 2003

(54) Color correction instruction apparatus

(75) Inventor: Hirokazu Kondo, Kanagawa (JP)

Correspondence Address: SUGHRUE, MION, ZINN,, MACPEAK & SEAS, PLLC, 2100 Pennsylvania Avenue, N.W., Washington, DC, 20037-3202, US

(73) Assignee: FUJI PHOTO FILM CO., LTD.

(21) Appl. No.: 10/194,294

(22) Filed: Jul. 15, 2002

(30) Foreign Application Priority Data
Jul. 30, 2001 (JP) 2001-230094

(51) Int. Cl. B41J 1/00; G06F 15/00; G03F 3/08

(52) U.S. Cl. 358/518; 358/1.9

(57) ABSTRACT

There is disclosed a color correction instruction apparatus for instructing correction of a color of an image represented by image data transmitted via a communication line. An image, which is subjected to a color correction processing upon receipt of an instruction of correction of a color of an image represented by image data transmitted via the communication line, is outputted. Data specifying the designated image from among outputted images is transmitted via the communication line.

### BACKGROUND OF THE INVENTION

1. Field of the Invention

The present invention relates to a color correction instruction apparatus for instructing correction of a color of an image represented by image data transmitted via a communication line.

2. Description of the Related Art

Hitherto, to perform printing of a color image using a printing machine, there is performed a prediction of finish of a printed image obtained through printing by the printing machine in such a manner that prior to printing a color printer is used to output a proof image which is extremely similar in color to a printed image obtained through printing by the printing machine, and the proof image is referred to.

To create a proof image by a color printer, the proof image is created in such a manner that a color reproduction characteristic (a printing profile) describing a relation between image data and colors of the actual printed matter, which is associated with a printing machine of interest, and a color reproduction characteristic (a printer profile) describing a relation between image data and colors of a proof image to be actually printed out, which is associated with a color printer for outputting the proof image, are identified; a color conversion definition consisting of a combination of the printing profile and the printer profile is created; image data for a printing is converted into image data for a printer in accordance with the color conversion definition; and the proof image is created in accordance with the image data for a printer thus converted. Thus, it is possible to create a proof image that is extremely similar in color to a printed image obtained through printing by the printing machine.

Further, recently, as communication network technology represented by Internet and the like advances, it is widely performed that proof image data, which is representative of a proof image created in a production side such as a printing company, is transmitted via a communication line to a client side located at a place that is geographically remote from the production side, and a color printer installed in the client side is used to output the same proof image as that obtained in the production side in accordance with the received proof image data. Means for obtaining the proof image at a remote place via the communication line is referred to as a “remote proof” hereinafter.

In case of the remote proof, for example, the color printer installed in the client side is managed in color, and it is guaranteed that a color represented by a color printer installed in the production side is always represented by the same color in the color printer installed in the client side too. The production side converts the proof image data, which is representative of the proof image created in the production side, into page description data of, for example, a PDF (Portable Document Format), and transmits the page description data together with the above-mentioned printing profile via the communication line to the client side. Under those conditions, the same proof image as that obtained in the production side is reproduced in the client side.

By the way, with respect to the instruction of a color proof from the client side to the production side, in a case where the client side receives the page description data of the PDF type, it is difficult to correct colors on the page description data of the PDF type. Thus, the instruction of the color proof is transferred to the production side, for example, in such a manner that a paper, into which contents of the instruction of the color correction are written, is sent by FAX to the production side. The production side corrects colors in accordance with the instruction of the color proof from the client side. However, the instruction of the color proof is made by the vague expressions, for example, “more little light”. Thus, it is difficult for the production side to immediately understand the color intended by the client side. Therefore, it often happens that the production side is obliged to have a plurality of number of times of color proof. This is very inefficient.

### SUMMARY OF THE INVENTION

In view of the foregoing, it is an object of the present invention to provide a color correction instruction apparatus capable of efficiently issuing instructions for color correction.

To achieve the above-mentioned object, the present invention provides a first color correction instruction apparatus comprising:

an image data receiving section for receiving image data transmitted via a communication line;

a color correction instruction section for instructing correction of a color of an image represented by the image data received by said image data receiving section in accordance with an operation;

an output section for outputting the image represented by the image data received by said image data receiving section and an image represented by at least one image data subjected to color correction processing according to correction of a color instructed by said color correction instruction section;

an image designation section for designating an optional image of the images outputted by said output section in accordance with an operation; and

a data transmission section for transmitting via the communication line data specifying an image designated by said image designation section.

According to the first color correction instruction apparatus, an image, which is subjected to a color correction processing upon receipt of an instruction of correction of a color of an image represented by image data transmitted via the communication line, is outputted. Data specifying the designated image from among the outputted images is transmitted via the communication line. Thus, it is possible for a transmitting side to exactly grasp the contents of color correction processing, which is applied to the image, from the data specifying the image, and as a result, it is possible to efficiently issue instructs for the color correction.

In the color correction instruction apparatus according to the present invention as mentioned above, it is preferable that said color correction instruction apparatus instructs correction of a color of an image for printing, and said color correction instruction apparatus deals with image data wherein a color is represented by a CMYK color space depending on printing.

Here, the CMYK color space depending on printing refers to a color space consisting of four colors of C (Cyan), M (Magenta), Y (Yellow) and K (Black) which are used for printing.

Dealing with image data wherein a color is represented by a CMYK color space depending on printing makes it possible for an operator to grasp the color reproduction area of a printing machine and then issue instructions for color correction.

In the color correction instruction apparatus of the present invention, dealing with image data wherein a color is represented by a CMYK color space depending on printing brings about the above-mentioned advantage. However, a correction instruction apparatus of the present invention is not restricted to such a correction instruction apparatus. It is acceptable that the correction instruction apparatus of the present invention is a correction instruction apparatus dealing with image data wherein a color is represented by a color space independent of a device, for example, an L*a*b* color space.

In the color correction instruction apparatus according to the present invention as mentioned above, it is preferable that the color correction instruction apparatus further comprises a color correction processing section for creating new image data in such a manner that a color correction processing according to correction of a color instructed by said color correction instruction section is applied to the image data received by said image data receiving section,

wherein said output section outputs the image represented by the image data received by said image data receiving section and an image represented by image data created by applying the color correction processing according to correction of a color instructed by said color correction instruction section.

According to the color correction instruction apparatus having the color correction processing section, it is possible to immediately an image subjected to the image correction processing.

In the color correction instruction apparatus according to the present invention as mentioned above, it is acceptable that said color correction instruction section instructs a direction of correction of a color of an image represented by the image data received by said image data receiving section, and said color correction processing section creates image data representative of an image in which a color is varied in a direction of correction of a color instructed by said color correction instruction section.

This feature makes it possible to obtain an image subjected to the color correction with simple operation.

In the color correction instruction apparatus according to the present invention as mentioned above, it is acceptable that the color correction instruction apparatus further comprises:

a color correction instruction transmission section for transmitting via the communication line an instruction of correction of a color by said color correction instruction section; and

a second image data receiving section for receiving image data subjected to a color correction processing according to the instruction of correction of a color from said color correction instruction transmission section,

wherein said output section outputs an image according to the image data received by said image data receiving section and said second image data receiving section.

According to the color correction instruction apparatus having the color correction instruction transmission section and the second image data receiving section, the image subjected to the color correction processing is received and transmitted. Accordingly, it is possible to designate a desired image from among the outputted images and transmit via the communication line data specifying the designated image. Thus, it is possible for a transmitting side to exactly grasp the contents of color correction processing, which is applied to the image, from the data specifying the image, and as a result, it is possible to efficiently issue instructs for the color correction.

To achieve the above-mentioned object, the present invention provides a second color correction instruction apparatus comprising:

an image data receiving section for receiving image data transmitted via a communication line;

an area designation section for designating a partial area of an image represented by the image data received by said image data receiving section in accordance with an operation;

a color correction instruction section for instructing correction of a color of the partial area designated by said area designation section in accordance with an operation;

an output section for outputting the image represented by the image data received by said image data receiving section and a color sample represented by at least one color sample data subjected to color correction processing according to correction of a color instructed by said color correction instruction section;

a color sample designation section for designating an optional color sample of the color samples outputted by said output section in accordance with an operation; and

a data transmission section for transmitting via the communication line data specifying a color sample designated by said color sample designation section.

According to the second color correction instruction apparatus, a color sample, which is subjected to a color correction processing upon receipt of an instruction of correction of a color of a partial area of an image represented by image data transmitted via the communication line, is outputted. Data specifying the designated color sample from among the outputted color samples is transmitted via the communication line. Thus, it is possible for a transmitting side to exactly grasp the contents of color correction processing, which is applied to the image, from the data specifying the image, and as a result, it is possible to efficiently issue instructs for the color correction.

### BRIEF DESCRIPTION OF THE DRAWINGS

FIG. 1 is a structural view of proof and printing image creation system to which an embodiment of the present invention is applied.

FIG. 2 is a perspective view of a personal computer 70 shown in FIG. 1.

FIG. 3 is a hardware structural view of the personal computer 70.

FIG. 4 is a functional block diagram showing a first embodiment of a first color correction instruction apparatus of the present invention.

FIG. 5 is a functional block diagram showing a second embodiment of a first color correction instruction apparatus of the present invention.

FIG. 6 is a functional block diagram showing an embodiment of a second color correction instruction apparatus of the present invention.

FIG. 7 is a view showing a first example of an image plane displayed on a display screen 72a (refer to FIG. 2) of an image display unit 72.

FIG. 8 is a view showing a second example of an image plane displayed on a display screen 72a (refer to FIG. 2) of an image display unit 72.

FIG. 9 is a view showing a third example of an image plane displayed on a display screen 72a (refer to FIG. 2) of an image display unit 72.

FIG. 10 is a view showing a fourth example of an image plane displayed on a display screen 72a (refer to FIG. 2) of an image display unit 72.

FIG. 11 is a view showing a fifth example of an image plane displayed on a display screen 72a (refer to FIG. 2) of an image display unit 72.

FIG. 12 is a view showing a sixth example of an image plane displayed on a display screen 72a (refer to FIG. 2) of an image display unit 72.

### DETAILED DESCRIPTION OF PREFERRED EMBODIMENTS

Embodiments of the present invention will be described with reference to the accompanying drawings.

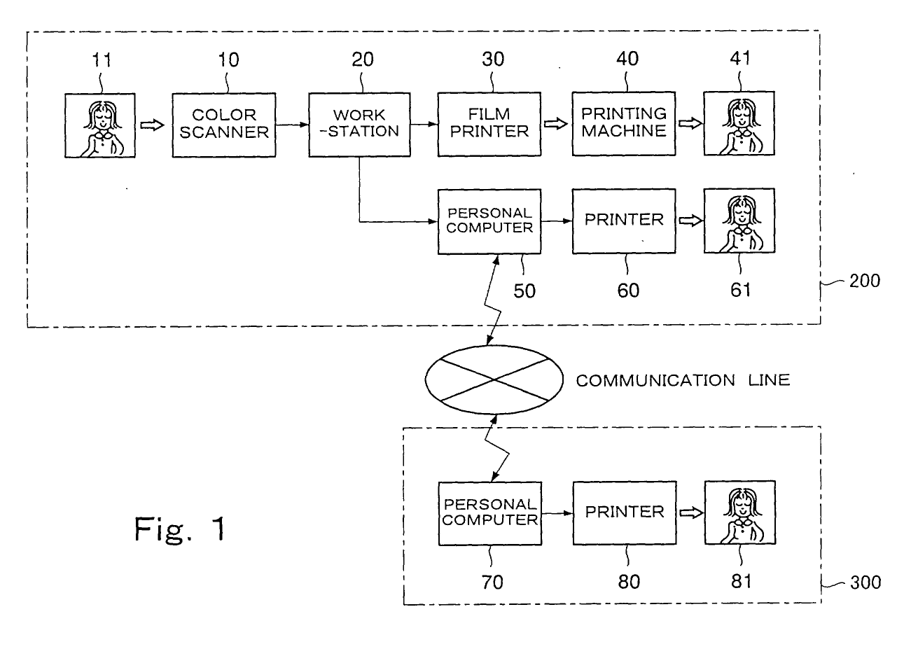

FIG. 1 is a structural view of a proof and printing image creation system to which an embodiment of the present invention is applied.

FIG. 1 shows a proof and printing image creation system comprising a production side 200 such as a printing company, a client side 300 and a communication line for connecting the production side 200 with the client side 300.

A color scanner 10 installed in the production side 200 reads an original image 11 to generate color separation image data for four colors consisting of C (Cyan), M (Magenta), Y (Yellow) and K (Black), which is representative of the original image 11 read. The color separation image data for CMYK is fed to a workstation 20. In the workstation 20, electronic page make-up is performed in accordance with the entered image data, so that image data representative of an image for printing is created. The image data for printing is fed to a film printer 30 in the event that the printing is performed. The film printer 30 creates printing film original plates for CMYK plates in accordance with the entered image data.

Machine plates are created from the printing film original plates. The machine plates thus created are mounted on a printing machine 40. Ink is applied to the machine plates mounted on the printing machine 40. The ink is transferred to a sheet for printing to form a printed image 41 on the sheet.

A series of works such that the film printer 30 creates the film original plates, machine plates are created from the film original plates and be mounted on the printing machine 40, and ink is applied to the machine plates to perform printing on a sheet is a large-scale work, and it takes a lot of cost. For this reason, prior to the actual printing work, there is performed a prediction for finish of the printed image 41 in such a manner that a printer 60 is used to create a proof image 61 as follows.

To create the proof image, the image data created by the electronic page make-up on the workstation 20 is fed to a personal computer 50. The image data fed to the personal computer 50 is description language data described in a so-called PDL (Page Description Language). In the personal computer 50, a so-called RIP (Raster Image Processor) converts the image data thus fed into image data for CMYK four colors developed into a bit map. The image data for CMYK four colors is substantially the same as the image data for printing fed to the film printer 30.

The printing image data for CMYK four colors is converted into image data for CMYK four colors suitable for the printer 60 referring to a color conversion definition having a format of LUT (Look Up Table) inside the personal computer 50. The printer 60 receives image data for CMYK four colors for the printer and creates the proof image 61 in accordance with the received image data for CMYK four colors for the printer.

The personal computer 50 installed in the production side 200 is connected via a communication line such as a public telephone line to a personal computer 70 installed in the client side 300. The personal computer 70 receives via the communication line a PDF format of image data in which a color is represented by a CMYK color space depending on printing together with a printing profile associated with the printing machine 40.

A printer 80 installed in the client side 300 is managed in color so that it is guaranteed that a color represented by the printer 60 is always represented by the same color also in the printer 80.

When the personal computer 70 receives via the communication line a PDF format of image data in which a color is represented by a CMYK color space depending on printing, based on the image data created by the electronic page make-up on the workstation 20, which is fed to the personal computer 50, together with the printing profile associated with the printing machine 40, the printing image data for CMYK four colors is converted into image data for CMYK four colors suitable for the printer 80 inside the personal computer 50. The printer 80 receives the image data for CMYK four colors for the printer and creates a proof image 81 in accordance with the received image data for CMYK four colors for the printer. The proof image 81 is the same as the proof image 61.

Thus, it is possible to predict finish of printing beforehand by creating a proof image and confirming the proof image.

In the system shown in FIG. 1, there are shown the printers 60 and 80 by way of examples for an image output apparatus for outputting a proof image based on image data. It is acceptable, however, that the printers 60 and 80 are an electrophotographic system of color printer, an ink jet system of color printer, or a printer of such a type of system that a photographic paper is exposed with the modulated laser beam and then developed. And thus any type of printer can be used regardless of a printing system. As far as it is guaranteed that a color represented by an image output apparatus installed in the production side 200 is always represented by the same color in an image output apparatus installed in the client side 300 too, the image output apparatus is not restricted to a printer, and it is acceptable that the image output apparatus is an image display unit, for example, a CRT display unit for displaying an image on a display screen and a plasma display unit.

Here, however, there will be explained a system having the printers 60 and 80 by way of example for an image output apparatus.

An aspect of the embodiment of the present invention, in the proof and printing image creation system, relates to processing contents to be executed by the personal computer 70. Thus, first, there will be explained the personal computer 70.

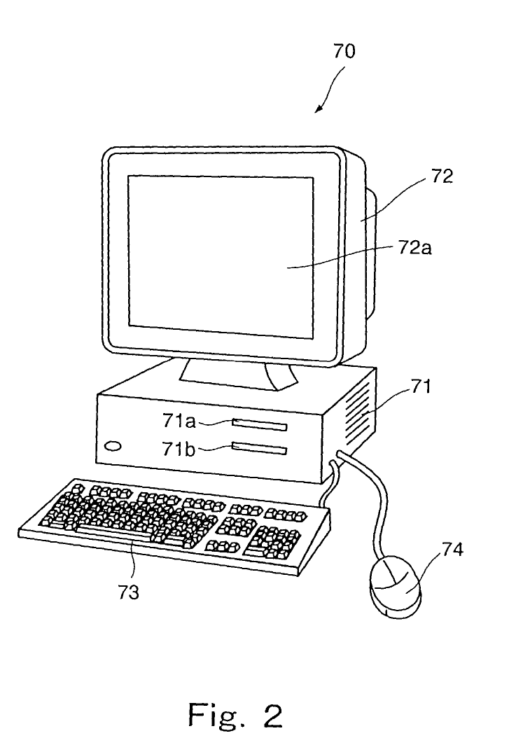

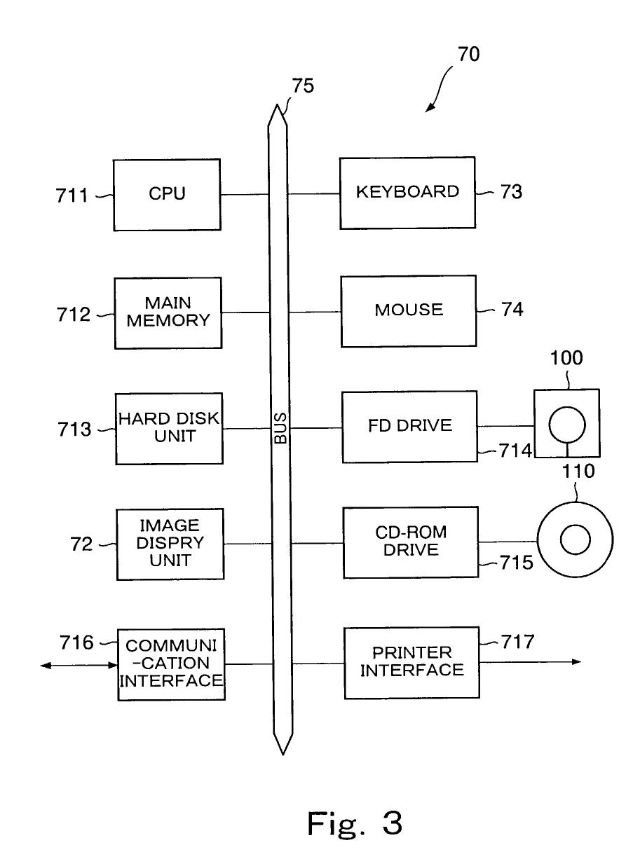

FIG. 2 is a perspective view of a personal computer 70 shown in FIG. 1. FIG. 3 is a hardware structural view of the personal computer 70.

The personal computer 70 comprises, on an external appearance, a main frame unit 71, an image display unit 72 for displaying an image on a display screen 72a in accordance with an instruction from the main frame unit 71, a keyboard 73 for inputting various sorts of information to the main frame unit 71 in accordance with a key operation, and a mouse 74 for inputting an instruction according to, for example, an icon and the like, through designation of an optional position on the display screen 72a, the icon and the like being displayed on the position on the display screen 72a. The main frame unit 71 has a flexible disk (FD) mounting slot 71a for mounting a flexible disk (FD), and a CD-ROM mounting slot 71b for mounting a CD-ROM.

The main frame unit 71 comprises, as shown in FIG. 3, a CPU 711 for executing a various types of program, a main memory 712 in which a program stored in a hard disk unit 713 is read out and developed for execution by the CPU 711, the hard disk unit 713 for saving various types of programs and data, an FD drive 714 for accessing a flexible disk 100 mounted thereon, a CD-ROM drive 715 for accessing a CD-ROM 110 mounted thereon, a communication interface 716 connected to a communication line to control a communication with another machine, and a printer interface 716 for transmitting image data to the printer 80. These various types of elements are connected via a bus 75 to the image display unit 72, the keyboard 73 and the mouse 74, which are shown also in FIG. 2.

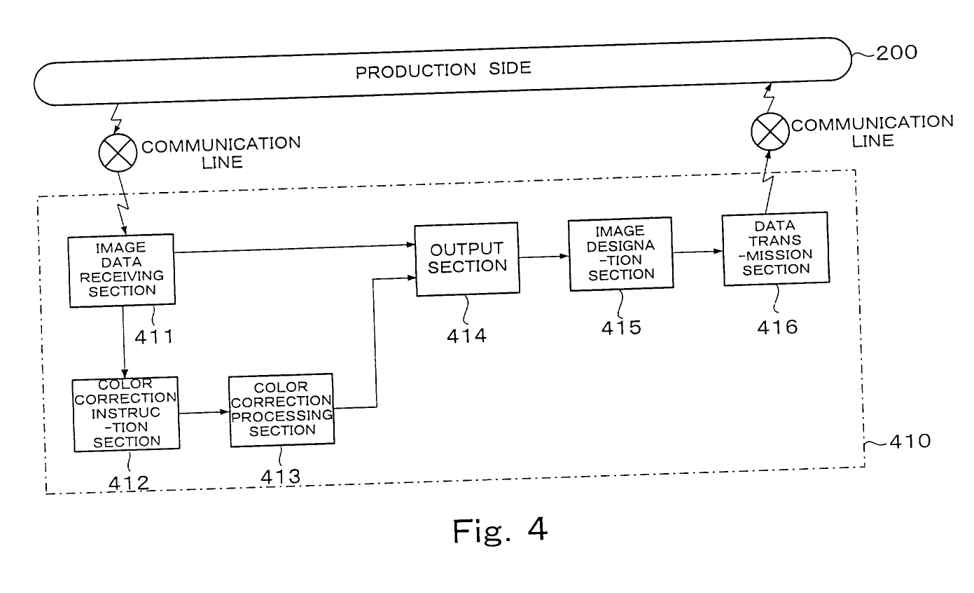

FIG. 4 is a functional block diagram showing a first embodiment of a first color correction instruction apparatus of the present invention.

FIG. 4 shows a printing and proof image creating system comprising a production side 200, a color correction instruction apparatus 410 corresponding to a first embodiment of a first color correction instruction apparatus of the present invention, which is installed in the client side 300 shown in FIG. 1, and communication lines for connecting the production side 200 with the color correction instruction apparatus 410.

The color correction instruction apparatus 410 comprises an image data receiving section 411, a color correction instruction section 412, a color correction processing section 413, an output section 414, an image designation section 415, and a data transmission section 416.

The image data receiving section 411 receives via the communication line image data wherein a color is represented by a CMYK color space depending on the printing. This image data receiving section 411 corresponds, on a hardware basis, to a combination of the keyboard 73 or the mouse 74, the image display unit 72, and the CPU 711, shown in FIG. 2 and FIG. 3.

The color correction instruction section 412 instructs a direction of correction of a color of an image for a printing, which is represented by the image data received by the image data receiving section 411, in accordance with an operation. This color correction instruction section 412 corresponds, on a hardware basis, to a combination of the keyboard 73 or the mouse 74, the image display unit 72, and the CPU 711, shown in FIG. 2 and FIG. 3.

The color correction processing section 413 processes the image data received by the image data receiving section 411 to generate image data representative of an image in which a color is varied in a direction of correction for color instructed by the color correction instruction section 412. This color correction processing section 413 corresponds, on a hardware basis, to a combination of the keyboard 73 or the mouse 74, the image display unit 72, and the CPU 711, shown in FIG. 2 and FIG. 3.

The output section 414 outputs an image represented by the image data received by the image data receiving section 411 and an image represented by the image data generated through the color correction processing by the color correction processing section 413. This output section 414 corresponds, on a hardware basis, to a combination of the keyboard 73 or the mouse 74, the image display unit 72, and the CPU 711, shown in FIG. 2 and FIG. 3.

The image designation section 415 designates an optional one of the images outputted from the output section 414 in accordance with an operation. This image designation section 415 corresponds, on a hardware basis, to a combination of the keyboard 73 or the mouse 74, the image display unit 72, and the CPU 711, shown in FIG. 2 and FIG. 3.

The data transmission section 416 transmits via the communication line data specifying the image designated by the image designation section 415. This data transmission section 416 corresponds, on a hardware basis, to a combination of the keyboard 73 or the mouse 74, the image display unit 72, and the CPU 711, shown in FIG. 2 and FIG. 3.

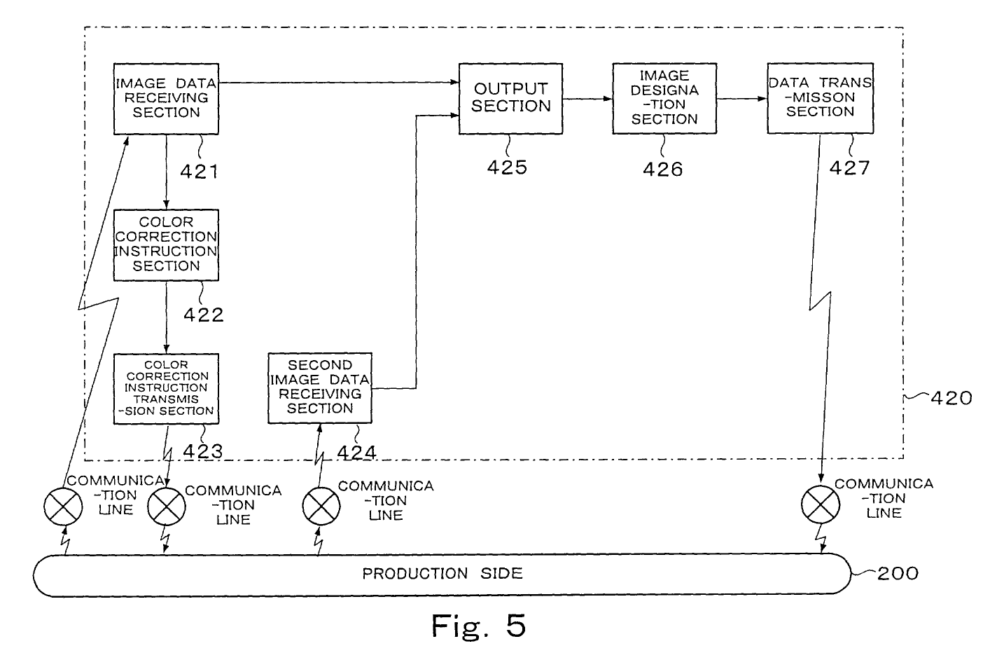

FIG. 5 is a functional block diagram showing a second embodiment of a first color correction instruction apparatus of the present invention.

FIG. 5 shows a printing and proof image creating system comprising a production side 200, a color correction instruction apparatus 420 corresponding to the second embodiment of the first color correction instruction apparatus of the present invention, which is installed in the client side 300 shown in FIG. 1, and communication lines for connecting the production side 200 with the color correction instruction apparatus 420.

The color correction instruction apparatus 420 comprises an image data receiving section 421, a color correction instruction section 422, a color correction instruction transmission section 423, a second image data receiving section 424, an output section 425, an image designation section 426, and a data transmission section 427.

The image data receiving section 421 receives via the communication line image data wherein a color is represented by a CMYK color space depending on the printing. This image data receiving section 421 corresponds, on a hardware basis, to a combination of the keyboard 73 or the mouse 74, the image display unit 72, and the CPU 711, shown in FIG. 2 and FIG. 3.

The color correction instruction section 422 instructs a direction of correction of a color of an image for a printing, which is represented by the image data received by the image data receiving section 421, in accordance with an operation. This color correction instruction section 422 corresponds, on a hardware basis, to a combination of the keyboard 73 or the mouse 74, the image display unit 72, and the CPU 711, shown in FIG. 2 and FIG. 3.

The color correction instruction transmission section 423 transmits via the communication line an instruction of correction of a color by the color correction instruction section 422. This color correction instruction transmission section 423 corresponds, on a hardware basis, to a combination of the keyboard 73 or the mouse 74, the image display unit 72, and the CPU 711, shown in FIG. 2 and FIG. 3.

The second image data receiving section 424 receives image data subjected to the color correction processing in accordance with the instruction of the color correction from the color correction instruction transmission section 423. This second image data receiving section 424 corresponds, on a hardware basis, to a combination of the keyboard 73 or the mouse 74, the image display unit 72, and the CPU 711, shown in FIG. 2 and FIG. 3.

The output section 425 outputs an image based on the image data received by the image data receiving section 421 and the image data received by the second image data receiving section 424. This output section 425 corresponds, on a hardware basis, to a combination of the keyboard 73 or the mouse 74, the image display unit 72, and the CPU 711, shown in FIG. 2 and FIG. 3.

The image designation section 426 designates an optional one of the images outputted from the output section 425 in accordance with an operation. This image designation section 426 corresponds, on a hardware basis, to a combination of the keyboard 73 or the mouse 74, the image display unit 72, and the CPU 711, shown in FIG. 2 and FIG. 3.

The data transmission section 427 transmits via the communication line data specifying the image designated by the image designation section 426. This data transmission section 427 corresponds, on a hardware basis, to a combination of the keyboard 73 or the mouse 74, the image display unit 72, and the CPU 711, shown in FIG. 2 and FIG. 3.

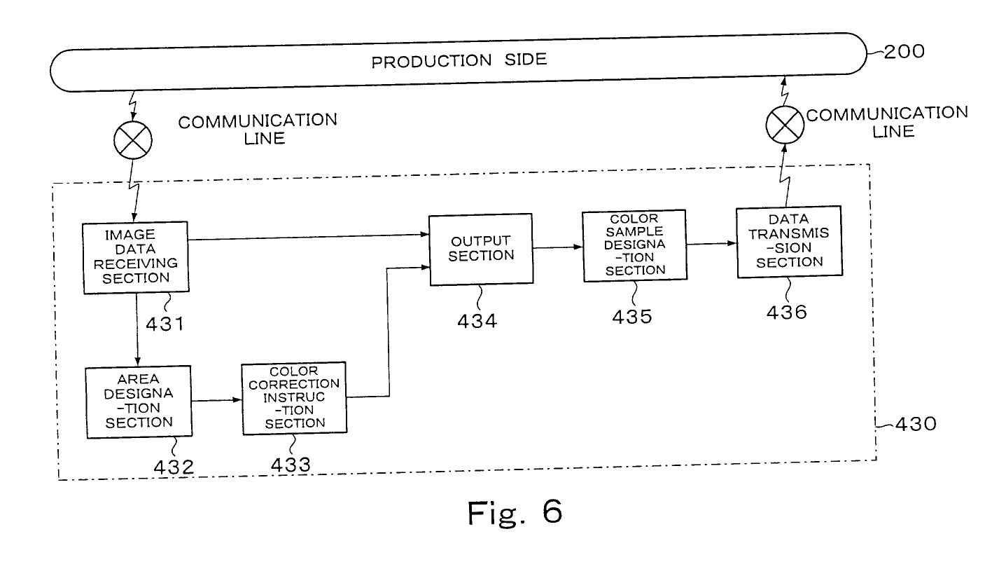

FIG. 6 is a functional block diagram showing an embodiment of a second color correction instruction apparatus of the present invention.

FIG. 6 shows a printing and proof image creating system comprising a production side 200, a color correction instruction apparatus 430 corresponding to an embodiment of a second color correction instruction apparatus of the present invention, which is installed in the client side 300 shown in FIG. 1, and communication lines for connecting the production side 200 with the color correction instruction apparatus 430.

The color correction instruction apparatus 430 comprises an image data receiving section 431, an area designation section 432, a color correction instruction section 433, an output section 434, a sample designation section 435, and a data transmission section 436.

The image data receiving section 431 receives via the communication line image data wherein a color is represented by a CMYK color space depending on the printing. This image data receiving section 431 corresponds, on a hardware basis, to a combination of the keyboard 73 or the mouse 74, the image display unit 72, and the CPU 711, shown in FIG. 2 and FIG. 3.

The area designation section 432 instructs a partial area of an image represented by the image data received by the image data receiving section 431, in accordance with an operation. This area designation section 432 corresponds, on a hardware basis, to a combination of the keyboard 73 or the mouse 74, the image display unit 72, and the CPU 711, shown in FIG. 2 and FIG. 3 .

The color correction instruction section 433 instructs correction of a color of the partial area designated by the area designation section 432, in accordance with an operation. This color correction instruction section 433 corresponds, on a hardware basis, to a combination of the keyboard 73 or the mouse 74, the image display unit 72, and the CPU 711, shown in FIG. 2 and FIG. 3.

The output section 434 outputs an image represented by the image data received by the image data receiving section 431 and a color sample represented by at least one color sample data subjected to the color correction processing according to correction of the color instructed by the color correction instruction section 433. This output section 434 corresponds, on a hardware basis, to a combination of the keyboard 73 or the mouse 74, the image display unit 72, and the CPU 711, shown in FIG. 2 and FIG. 3.

The color sample designation section 435 designates an optional one of the color samples outputted from the output section 434 in accordance with an operation. This color sample designation section 435 corresponds, on a hardware basis, to a combination of the keyboard 73 or the mouse 74, the image display unit 72, and the CPU 711, shown in FIG. 2 and FIG. 3.

The data transmission section 436 transmits via the communication line data specifying the color sample designated by the color sample designation section 435. This data transmission section 436 corresponds, on a hardware basis, to a combination of the keyboard 73 or the mouse 74, the image display unit 72, and the CPU 711, shown in FIG. 2 and FIG. 3.

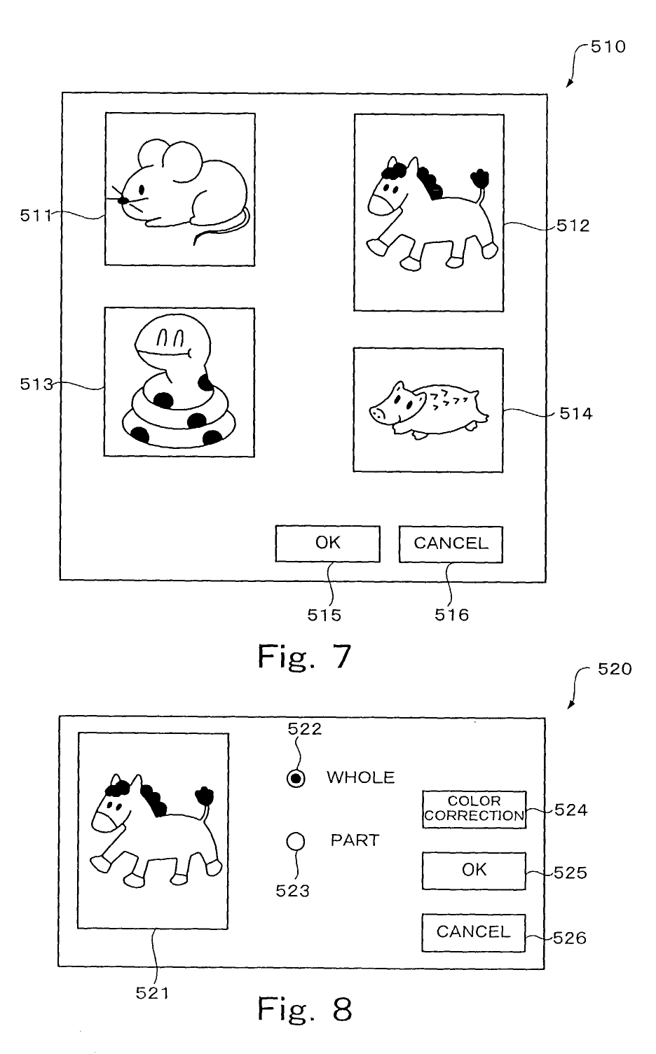

FIG. 7 is a view showing a first example of an image plane displayed on a display screen 72a (refer to FIG. 2) of an image display unit 72.

A picture plane 510 is displayed on the display screen 72a of an image display unit 72 of the personal computer 70 shown in FIG. 1, FIG. 2 and FIG. 3, when a predetermined operation is performed by the keyboard 73 or the mouse 74 of the personal computer 70.

On the picture plane 510 there are displayed four images 511, 512, 513 and 514 represented by image data wherein a color is represented with the CMYK color space depending on the printing, which is transmitted via the communication line and received by the image data receiving section of the present invention. Lower right of the picture plane 510 there is provided an OK button 515. When an image, which is to be subjected to the color correction processing, from among the four images 511, 512, 513 and 514, that is, here the image 512, is selected in such a manner that an operator sets the mouse pointer to an optional position on the image 512 in accordance with the mouse operation and clicks, and then the OK button 515 is clicked, a picture plane 520 (cf. FIG. 8) is displayed in form of a window different from the picture plane 510, while the picture plane 510 is kept on display.

Further, on the right side of the OK button 515, there is provided a cancel button 516. When the cancel button 516 is clicked, the picture plane 510 is closed.

FIG. 8 is a view showing a second example of an image plane displayed on a display screen 72a (refer to FIG. 2) of an image display unit 72.

A picture plane 520 is displayed when the image 512 shown in FIG. 7 is selected and the OK button 515 is clicked. In the event that the picture plane 520 is displayed after the OK button 515 is clicked, an image 521, which is the same as the selected image 512, is displayed on the left of the picture plane 520.

On the right of the image 521, there are provided two radio buttons. Of the two radio buttons, a “whole” radio button 522 is selected in the event that the color correction processing is applied to the selected image 521 in its entirety. Another one, a “part” radio button 523, is selected in the event that the color correction processing is applied to a partial area of the selected image 521, which is designated through the area designation section of the present invention in accordance with an operation. According to the present embodiment, the “whole” radio button 522 is selected.

Hereinafter, first, there will be explained an example in which the color correction processing is applied to the selected image 521 in its entirety.

On the right side of the radio buttons shown in FIG. 8, there are provided a color correction button 524, an OK button 525 and a cancel button 526. When the color correction button 524 is clicked after either one of the above-mentioned two radio buttons is selected, the color correction processing associated with the selected radio button can be implemented.

The OK button 525 is set up so that the OK button 525 is prevented from being clicked before any one of color correction processing, which will be explained hereinafter, is applied. According to the present embodiment, when any one of color correction processing, which will be explained hereinafter, is applied, all the contents of the applied color correction processing are stored. Data representative of the contents of the color correction processing thus stored specifies the applied color correction processing. When the OK button 525 is clicked after the color correction processing is applied, data specifying the color correction processing is automatically written in the vicinity of the image shown in FIG. 7, which is associated with the image subjected to the color correction processing, in form of notes. When the data transmission section of the present invention transmits via the communication line one wherein data specifying the color correction processing is written in form of notes, the production side 200 (cf. FIG. 1), which receives the data may exactly grasps the contents of the color correction processing in accordance with the data.

When the cancel button 526 is clicked, the operation after opening the picture plane 520 is annulled and the picture plane 520 is closed.

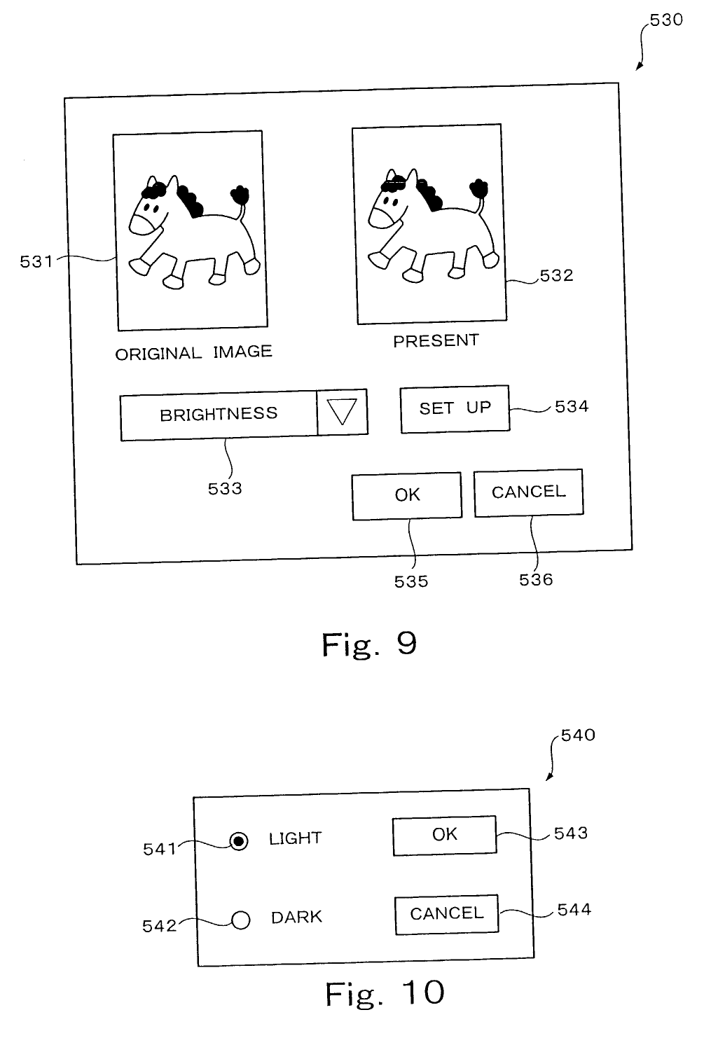

FIG. 9 is a view showing a third example of an image plane displayed on a display screen 72a (refer to FIG. 2) of an image display unit 72.

A picture plane 530 is displayed when the “whole” radio button 522 shown in FIG. 8 is selected and the color correction button 524 is clicked.

An image 531, which is the same as the image 512 selected in the picture plane 510 shown in FIG. 7 by the output section of the present invention, is displayed on the upper left of the picture plane 530. An image 532, which is subjected to the color correction processing at the time when the picture plane 530 is opened, is displayed on the right of the image 531 by the output section. It is noted, however, that in the event that the color correction processing is not yet applied, the same image as the image 531 is displayed.

Below the image 531, there is provided a list box 533 for selecting contents of color correction processing when the color correction processing is applied to the image 531 in its entirety. When a mark “∇” at the right end of the list box 533 is clicked, a list of contents of color correction processing (not illustrated) is displayed. In the list of contents of color correction processing, there are displayed contents of color correction processing, for example, “brightness”, “density”, “contrast”, “saturation” and “color phase”. When a desired one of the contents of color correction processing in the list of contents of color correction processing is clicked, one content of color correction processing is selected. According to the present embodiment, the “brightness” is selected.

At the right side of the list box 533, there is provided a set up button 534. When the set button 534 is clicked, there is displayed a picture plane 540 (cf. FIG. 10) for set up a direction of color correction as to the content of color correction processing selected in the list box 533, which will be described later.

Below the set up button 534, there are provided an OK button 535 and a cancel button 536. The OK button 535 is set up so that the OK button 535 is prevented from being clicked before any one of color correction processing, which will be explained hereinafter, is applied. When the OK button 535 is clicked after any one of the color correction processing is applied, the screen returns to the picture plane 520 shown in FIG. 8, on which an image subjected to the color correction processing is displayed for the image 521 shown in FIG. 8.

When the cancel button 536 is clicked, the operation after opening the picture plane 530 is annulled and the picture plane 530 is closed.

FIG. 10 is a view showing a fourth example of an image plane displayed on a display screen 72a (refer to FIG. 2) of an image display unit 72.

A picture plane 540 is displayed when the set up button 534 shown in FIG. 9 is clicked.

At the left side of the picture plane 540, there is provided two radio buttons. Of the two radio buttons, a “light” radio button 541 is selected in the event that the color correction processing is applied to the image 531 shown in FIG. 9 in its entirety in a light direction in accordance with the color correction instruction section of the present invention. Another one, a “dark” radio button 542, is selected in the event that the color correction processing is applied to the image 531 shown in FIG. 9 in its entirety in a light direction in accordance with the color correction instruction section of the present invention. According to the present embodiment, the “light” radio button 541 is selected.

On the right side of the radio buttons shown in FIG. 10, there are provided an OK button 543 and a cancel button 544. When the OK button 543 is clicked, the color correction processing associated with the selected radio button can be implemented.

When the cancel button 544 is clicked, the operation after opening the picture plane 540 is annulled and the picture plane 540 is closed.

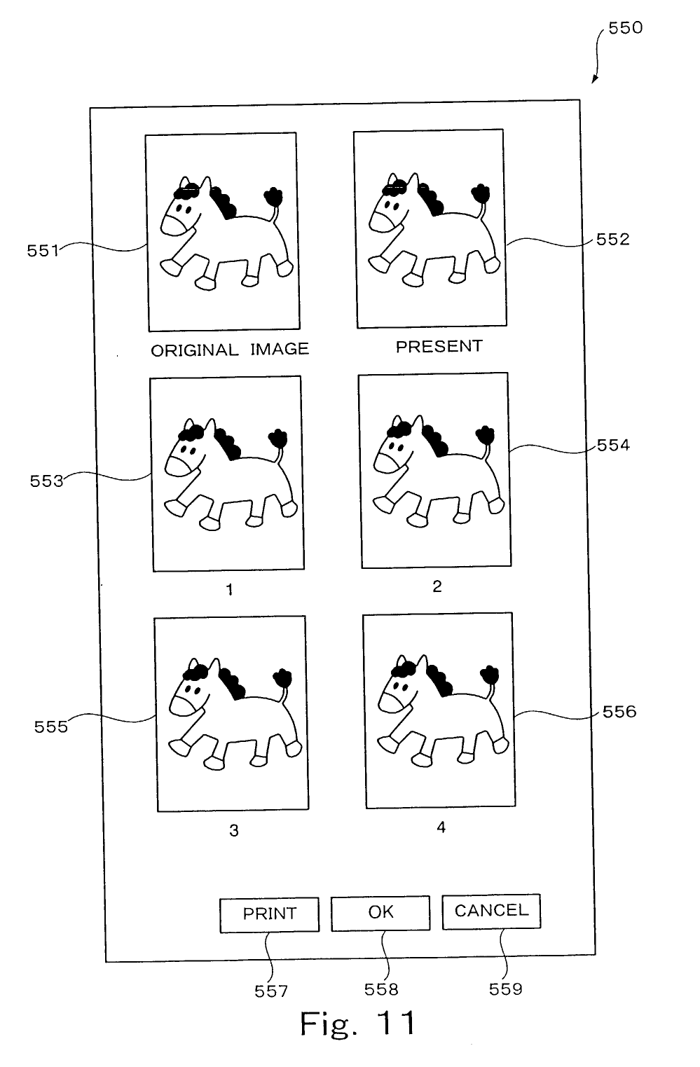

FIG. 11 is a view showing a fifth example of an image plane displayed on a display screen 72a (refer to FIG. 2) of an image display unit 72.

A picture plane 550 is displayed when the OK button 543 shown in FIG. 10 is clicked.

On the upper left of the picture plane 550, there is displayed an image 551, which is the same as the image 512 selected on the picture plane 510 shown in FIG. 7, by the output section of the present invention. An image 552, which is subjected to the color correction processing at the time when the picture plane 550 is opened, is displayed on the right of the image 551 by the output section. It is noted, however, that in the event that the color correction processing is not yet applied, the same image as the image 551 is displayed.

Below the images 551 and 552, there are displayed four images 553, 554, 555 and 556. Those four images 553, 554, 555 and 556 are images subjected to the color correction processing associated with the radio button selected on the picture plane 540 shown in FIG. 10. According to the present embodiment, there are shown the images 553, 554, 555 and 556 subjected to the color correction processing in the lighter direction in the named order by the color correction instruction section of the present invention in accordance with selection of the “light” radio button 541 on the picture plane 540 shown in FIG. 10.

When an image, which is to be subjected to a desired color correction processing, from among the four images 553, 554, 555 and 556, is selected in such a manner that an operator sets the mouse pointer to an optional position on the image in accordance with the mouse operation and clicks, and the image subjected to the selected color correction processing is displayed for the image 552 displayed upper right the picture plane 550.

Below the four images 553, 554, 555 and 556, there are provided a print button 557, an OK button 558, and a cancel button 559. When the print button 557 is clicked, there are created images including an image subjected to the color correction processing in the designated direction, which is represented by the same color as finish of printing by the printer 80 connected to the personal computer 70 shown in FIG. 1, FIG. 2 and FIG. 3.

After confirmation of colors through an image represented by the same color as finish of printing of printing by the printer 80, when an image, which is to be subjected to a desired color correction processing, from among the four images 553, 554, 555 and 556 shown in FIG. 11, is selected in such a manner that an operator sets the mouse pointer to an optional position on the image in accordance with the mouse operation and clicks, and the OK button 558 is clicked, the selected color correction processing is settled, and the screen returns to the picture plane 530 shown in FIG. 9, on which an image subjected to the selected color correction processing is displayed for the image 532 shown in FIG. 9.

When the cancel button 559 is clicked, the operation after opening the picture plane 550 is annulled and the picture plane 550 is closed.

Repetition of the operation as mentioned above using FIG. 9 to FIG. 11 makes it possible to repeatedly apply a desired color correction processing to the image 512 selected on the picture plane 510 shown in FIG. 7 in its entirety.

Next, there will be explained an example in which a partial area of the image 512 selected on the picture plane 510 shown in FIG. 7 is designated through the area designation section of the present invention in accordance with an operation, and the color correction processing is applied to the partial area.

When the “part” radio button 523 shown in FIG. 8 is selected, the mouse cursor is changed in shape to “+” and it is permitted to select an optional partial area on the image 521 shown in FIG. 8 through the area designation section of the present invention.

When the color correction button 524 shown in FIG. 8 is clicked after the optional partial area on the image 521 shown in FIG. 8 is selected, the color correction processing, in which the color correction processing is applied to the partial area, is implemented.

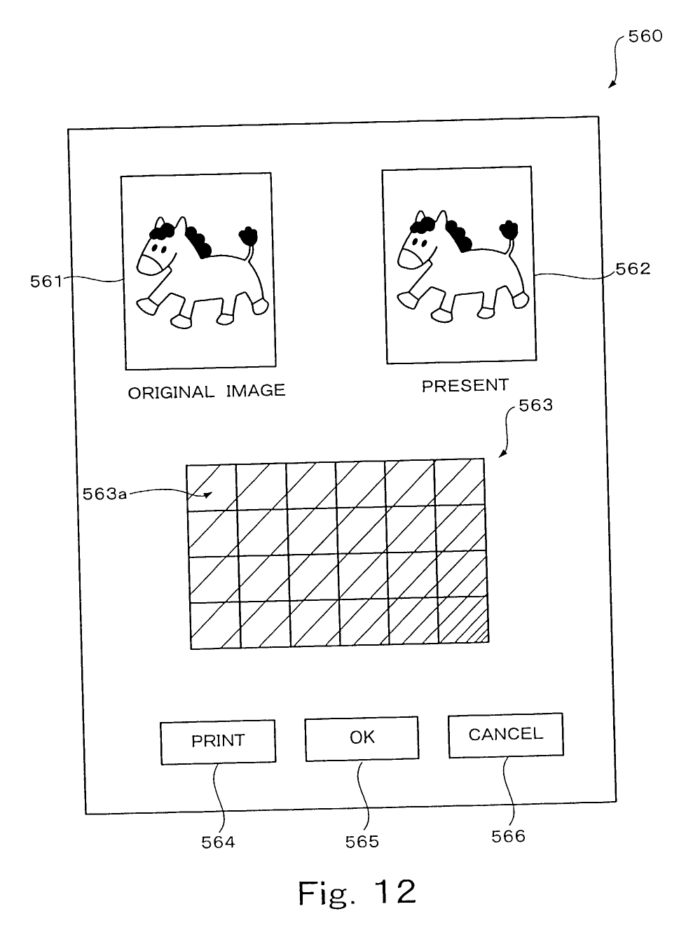

FIG. 12 is a view showing a sixth example of an image plane displayed on a display screen 72a (refer to FIG. 2) of an image display unit 72.

A picture plane 560 is displayed when the “part” radio button 523 shown in FIG. 8 is selected and the color correction button 524 is clicked.

At the upper left of the picture plane 560, there is displayed by the output section of the present invention an image 561 which is same as the image 512 selected on the picture plane 510 shown in FIG. 7. At the right side of the image 561, there is displayed by the output section of the present invention an image 562 subjected to the color correction processing on the partial area at the time point when the picture plane 560 is opened, wherein the partial area is encircled with the dotted line. However, in the event that the color correction processing is not yet applied to the partial area, an image, which is the same as the image 561, is displayed wherein the partial area selected on the image 521 shown in FIG. 8 is encircled with the dotted line.

Below the images 561 and 562, there is displayed by the output section of the present invention a color patch arrangement image wherein a plurality of color patches, in which CMYK dot % of the color of the partial area selected on the image 521 shown in FIG. 8 is varied, is arranged. Hereinafter, the color patch arrangement image wherein the plurality of color patches is arranged is referred to as a color sample 563. Of the plurality of color patches constituting the color sample 563, a color patch 563a at the upper left is a color patch represented by the same color as the partial area selected on the image 521 shown in FIG. 8.

Below the color sample 563, there are provided a print button 564, an OK button 565, and a cancel button 566. When the print button 564 is clicked, there are created images including the color sample 563 which is represented by the same color as finish of printing by the printer 80 connected to the personal computer 70 shown in FIG. 1, FIG. 2 and FIG. 3.

After confirmation of colors through a color sample represented by the same color as finish of printing of printing by the printer 80, when a color patch is selected in such a manner that an operator sets the mouse pointer to a desired color patch position of the color sample 563 shown in FIG. 12 in accordance with the mouse operation and clicks, and the OK button 565 is clicked, the color correction processing for the partial area is settled, and the screen returns to the picture plane 520 shown in FIG. 8, on which an image subjected to the color correction processing for the partial area is displayed for the image 521 shown in FIG. 8.

When the cancel button 566 is clicked, the operation after opening the picture plane 560 is annulled and the picture plane 560 is closed.

Repetition of the operation as mentioned above using FIG. 9 to FIG. 12 makes it possible to repeatedly apply a desired color correction processing to the image 512 selected on the picture plane 510 shown in FIG. 7 in its entirety or in part.

According to the present embodiments, there is explained by way of example a color correction instruction apparatus dealing with image data wherein a color is represented by a CMYK color space depending on printing. However, a correction instruction apparatus of the present invention is not restricted to such a correction instruction apparatus. It is acceptable that the correction instruction apparatus of the present invention is a correction instruction apparatus dealing with image data wherein a color is represented by a color space independent of a device, for example,.an L*a*b* color space.

Further, according to the present embodiments, as a color correction processing section for creating image data representative of an image in which a color is varied in a direction of a color correction instructed by the color correction instruction section, as shown in FIG. 11, there is explained by way of example a color correction instruction section for creating image data representative of an image in which a color is varied in a direction of a color correction on a four-step basis. However, a color correction instruction section of the present invention is not restricted to such a color correction instruction section. It is acceptable that a color correction instruction section of the present invention is for example a color correction instruction section for creating image data representative of an image in which a color is varied in a direction of a color correction in accordance with a moving amount of a slider provided in a picture plane, which slider is moved right and left by a mouse.

Furthermore, according to the examples of the picture planes displayed on the display screen 72a (refer to FIG. 2) of the image display unit 72, which are shown in FIG. 7 to FIG. 12, there is explained by way of example one for creating new image data by applying the color correction processing according to the color correction instructed by the color correction instruction section in the personal computer 70 installed in the client side 300 shown in FIG. 1 corresponding to the color correction instruction apparatus of the present invention. However, the present invention is not restricted to this one. The present invention is applicable to one in which an instruction for color correction by the color correction instruction section is transmitted via a communication line to the production side 200, and an image, which is subjected to the color correction processing in the production side 200 in accordance with the color correction, is received by the client side 300.

As mentioned above, according to the present invention, it is possible to provide a color correction instruction apparatus capable of efficiently giving an instruction for color correction.

While the present invention has been described with reference to the particular illustrative embodiments, it is not to be restricted by those embodiments but only by the appended claims. It is to be appreciated that those skilled in the art can change or modify the embodiments without departing from the scope and sprit of the present invention.

What is claimed is:

1. A color correction instruction apparatus comprising:
an image data receiving section for receiving image data transmitted via a communication line;
a color correction instruction section for instructing correction of a color of an image represented by the image data received by said image data receiving section in accordance with an operation;
an output section for outputting the image represented by the image data received by said image data receiving section and an image represented by at least one image data subjected to color correction processing according to correction of a color instructed by said color correction instruction section;
an image designation section for designating an optional image of the images outputted by said output section in accordance with an operation; and
a data transmission section for transmitting via the communication line data specifying an image designated by said image designation section.

2. A color correction instruction apparatus according to claim 1, wherein said color correction instruction apparatus instructs correction of a color of an image for printing, and
wherein said color correction instruction apparatus deals with image data wherein a color is represented by a CMYK color space depending on printing.

3. A color correction instruction apparatus according to claim 1, further comprising a color correction processing section for creating new image data in such a manner that a color correction processing according to correction of a color instructed by said color correction instruction section is applied to the image data received by said image data receiving section,
wherein said output section outputs the image represented by the image data received by said image data receiving section and an image represented by image data created by applying the color correction processing according to correction of a color instructed by said color correction instruction section.

4. A color correction instruction apparatus according to claim 3, wherein said color correction instruction section instructs a direction of correction of a color of an image represented by the image data received by said image data receiving section, and said color correction processing section creates image data representative of an image in which a color is varied in a direction of correction of a color instructed by said color correction instruction section.

5. A color correction instruction apparatus according to claim 1, further comprising:
a color correction instruction transmission section for transmitting via the communication line an instruction of correction of a color by said color correction instruction section; and
a second image data receiving section for receiving image data subjected to a color correction processing according to the instruction of correction of a color from said color correction instruction transmission section,
wherein said output section outputs an image according to the image data received by said image data receiving section and said second image data receiving section.

6. A color correction instruction apparatus comprising:
an image data receiving section for receiving image data transmitted via a communication line;
an area designation section for designating a partial area of an image represented by the image data received by said image data receiving section in accordance with an operation;
a color correction instruction section for instructing correction of a color of the partial area designated by said area designation section in accordance with an operation;
an output section for outputting the image represented by the image data received by said image data receiving section and a color sample represented by at least one color sample data subjected to color correction processing according to correction of a color instructed by said color correction instruction section;
a color sample designation section for designating an optional color sample of the color samples outputted by said output section in accordance with an operation; and
a data transmission section for transmitting via the communication line data specifying a color sample designated by said color sample designation section.
